(19) United States
(12) Patent Application Publication
(10) Pub. No.: US 2003/0206442 A1
(43) Pub. Date: Nov. 6, 2003

(54) Flash memory bridiging device, method and application system

(76) Inventors: Jerry Tang, Taipei (TW); Charlie Han, Hsinchu (TW); Pu-Ju Shen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/063,911

(22) Filed: May 23, 2002

(30) Foreign Application Priority Data
May 2, 2002 (TW) 91109119

(51) Int. Cl. G11C 16/04

(52) U.S. Cl. 365/185.17

(57) ABSTRACT

A flash memory bridging device, method and application system. The flash memory bridging device provides a buffer region that serves as a cache for storing the address of a portion of a NAND flash memory. A cache control logic inside the flash memory bridging device is used to determine if the requested data is a cache hit so that a direct response is possible or a cache miss so that waiting is demanded. During a data read operation, an error correction function is implemented so that data errors are corrected. Using NAND flash memory to simulate the operation of the NOR flash memory and store program code and data not only lowers production cost, but also improves overall performance and reliability of the system.

### CROSS REFERENCE TO RELATED APPLICATIONS

This application claims the priority benefit of Taiwan application serial no. 91109119, filed May 2, 2002.

### BACKGROUND OF INVENTION

1. Field of Invention

The present invention relates to a flash memory bridging device. More particularly, the present invention relates to a device, a method and an application system that uses a NAND flash memory to simulate the operation of a NOR flash memory.

2. Description of Related Art

As electronic technologies continue to improve, all types of information products including but not limited to the desktop computer, notebook computer and personal digital assistant (PDA), have been developed. To store the up boot code and to facilitate program code renewal, a NOR type flash memory is used. The NOR type flash memory has a fast operating speed and a great operating stability but is relatively expensive. On the other hand, a NAND type flash memory is often used for holding data. The NAND type flash memory is less expensive but has a slower operating speed and an inferior operating stability. Hence, the NAND type flash memory is less suitable for storing boot code. Due to such limitations, most information products use NOR flash memory as a storage medium for holding boot code leading to a higher production cost. If low-price NAND flash memory is used as a storage medium for boot code, operating efficiency and reliability are compromised. Thus, it is nearly impossible to get the best of both worlds.

### SUMMARY OF INVENTION

Accordingly, one object of the present invention is to provide a flash memory bridging device, method and application system that uses less efficient and reliable NAND type flash memory to simulate the operation of more efficient and reliable NOR type flash memory. Ultimately, performance and reliability of the memory is improved yet production cost of various information products is lowered.

To achieve these and other advantages and in accordance with the purpose of the invention, as embodied and broadly described herein, the invention provides a flash memory bridging device for simulating the operation of a NOR type flash memory using a NAND type flash memory so that the simulated memory may connect with a NOR flash memory interface. The flash memory bridging device includes a buffer region and a control logic. The buffer region stores data corresponding to a portion of the NAND flash memory addresses. The control logic is coupled to the buffer region for receiving memory instructions and determining, executing, and responding to the request implied by the memory instruction.

In one embodiment of this invention, the control logic further includes a first buffer access unit, a buffer control logic, a second buffer access unit, an error correction code unit, a block address translation table unit, a NAND flash memory control unit and a main control logic unit. The first buffer access unit serves as an access interface between the NOR flash memory interface and a buffer region. The buffer control logic is coupled to the first buffer access unit and the buffer region for controlling read/write operations in the buffer region. The second buffer access unit is coupled to the buffer control logic serving as an access interface between the NAND flash memory and the buffer region. The error correction code unit is coupled to the second buffer access unit for correcting errors when data is read from the NAND flash memory. The block address translation table unit is coupled to the second buffer access unit for converting the logic address of the memory instruction into an actual address. The NAND flash memory control unit is coupled to the error correction code unit and the block address translating table unit for read/write access of the NAND flash memory. The main control logic unit is coupled to the first buffer access unit, the second buffer access unit and the block address translating table unit. The main control unit controls the reading from the NAND flash memory data that has not been registered in the buffer region, determines if the data requested through the memory instruction is already stored in the buffer region and controls the writing of data temporarily stored in the buffer region into the NAND flash memory.

The list of memory instructions includes a memory read instruction, a memory write instruction and a memory configuration instruction. The control logic inside the flash memory bridging device supports 8/16/32 bit synchronous/asynchronous NOR flash memory interface, memory configurations such as 4M×8, 16M×8, 32M×8, 64M×8 and interleave and non-interleave mode of operation. On first switching on a machine, the boot code within the NAND flash memory is first transferred into the buffer region so that execution in place (XIP) is supported.

In this invention, the flash memory bridging device may also be applied to an application system. The application system includes a memory control chip, a NAND flash memory and a flash memory bridging device. The memory control chip supports a NOR flash memory interface that connects with a NOR flash memory. The NAND flash memory holds program code or data required by the system. The flash memory bridging device is coupled to the memory control chip and the NAND flash memory for using the NAND flash memory to simulate the operation of the NOR flash memory.

This invention also provides a bridge method for connecting a NAND flash memory with a NOR flash memory interface via a flash memory bridging device. The NAND flash memory and the flash memory bridging device together simulate the operation of a NOR flash memory. The bridging method includes the following steps. First, a memory instruction is received. If the memory instruction is a memory read instruction and the requested data is already recorded inside the flash memory bridging device, respond directly to the memory read instruction. If the memory instruction is a memory read instruction and the requested data is not found inside the flash memory bridging device, the data is read in from the NAND flash memory before responding to the memory read instruction. If the memory instruction is a memory write instruction, the data is stored inside the flash memory bridging device before gradually transferring the data to the NAND flash memory. If the memory instruction is a memory configuration instruction, the memory configuration instruction is executed. To improve data reliability, data read out from the NAND flash memory is error-corrected before sending to the flash memory bridging device.

In brief, this invention provides a flash memory bridging device, method and application system that uses low cost NAND flash memory to simulate the operation of high performance NOR flash memory. Hence, production cost is reduced but performance is improved.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram showing a typical application of conventional flash memory;

FIG. 2 is a schematic diagram showing the application of a flash memory bridging device according to one preferred embodiment of this invention;

FIG. 3 is a block diagram showing various components inside a flash memory bridging device according to one preferred embodiment of this invention; and

FIG. 4 is a flow chart showing the steps required to bridge flash memory according to this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

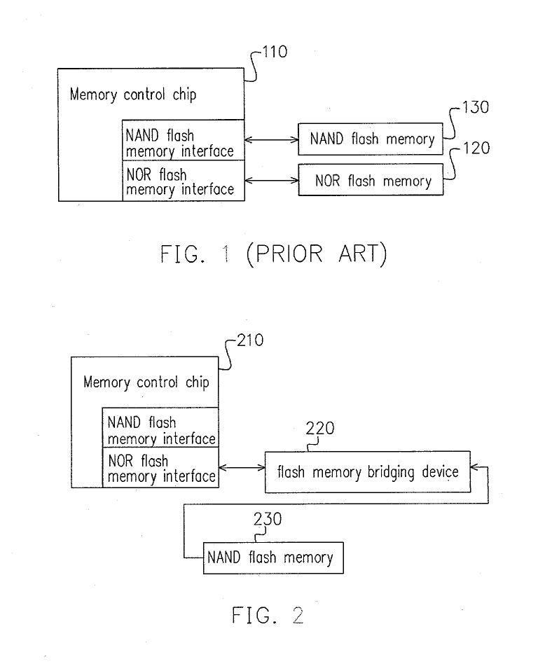

FIG. 1 is a schematic diagram showing a typical application of conventional flash memory. The system as shown in FIG. 1 may be applied to a desktop computer, a notebook computer or a personal digital assistant (PDA). Program code and data are stored inside different types of flash memory. The system includes a memory control chip 110, a NAND flash memory unit 130 and a NOR flash memory unit 120. The memory control chip 110 has a NAND flash memory interface and a NOR flash memory interface for connecting with a NAND flash memory 130 and a NOR flash memory 120 respectively. Since the NOR flash memory 120 has a better performance and reliability than the NAND flash memory 130, the NOR flash memory 120 is generally used for storing program codes. The NAND flash memory 130 is generally used for storing data.

However, the NOR flash memory 120 is more expensive to produce than the NAND flash memory 130 rendering further reduction of overall manufacturing cost impossible. On the other hand, if program code is stored using NAND flash memory 130, system performance and reliability are compromised. This invention provides a flash memory bridging device capable of boosting the performance and reliability of a NAND flash memory for holding program code with little additional cost.

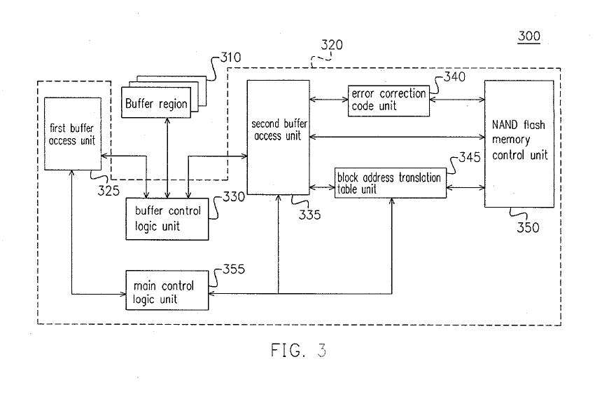

FIG. 2 is a schematic diagram showing the application of a flash memory bridging device according to one preferred embodiment of this invention. As shown in FIG. 2, the system includes a memory control chip 210, a NAND flash memory 230 for storing program codes and a flash memory bridging device 220. The flash memory bridging device 220 is coupled to the memory control chip 210 and the NAND flash memory 230. The flash memory bridging device uses the NAND flash memory 230 to simulate the operation of a NOR flash memory so that the performance and reliability demanded for storing program code is attained. Obviously, anyone familiar with memory partitioning may divide the NAND flash memory 230 into separate regions for holding program codes and data.

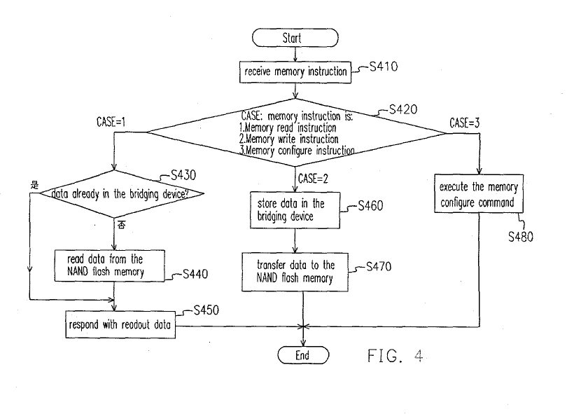

FIG. 3 is a block diagram showing various components inside a flash memory bridging device according to one preferred embodiment of this invention. As shown in FIG. 3, a flash memory bridging device 300 includes a buffer region 310 and a control logic unit 320. The buffer region 310 may have a single or a plurality of buffering devices such as FIFO or RAM for holding a portion of the address data of the NAND flash memory 230. If the buffer region includes several buffering devices, an interleave access mode may be employed to boost system performance. The control logic unit 320 is coupled to the buffer region 310 for receiving memory instructions, determining the content of the instruction, executing the instruction and responding to the request demanded by the instruction.

The control logic unit 320 further includes a buffer access unit 325, a buffer control logic unit 330, a second buffer access unit 335, an error correction code unit 340, a block address translation table unit 345, a NAND flash memory control unit 350 and a main control logic unit 355. The first buffer access unit 325 serves a similar function to the NOR flash memory interface within the memory control chip 210 as shown in FIG. 2 as an access interface with the buffer region 310. The buffer control logic unit 330 is coupled to the first buffer access unit 325, the second buffer access unit 335 and the buffer region 310 for controlling reading/writing in the buffer region 310. The second buffer access unit 335 is coupled to the buffer control logic unit 330 to serve a similar function to the NAND flash memory 230 as shown in FIG. 2 as an access interface for the buffer region 310. The error correction code unit 340 is coupled to the second buffer access unit 335 for correcting read-out data from the NAND flash memory as shown in FIG. 2. The block address translation table unit 345 is coupled to the second buffer access unit 335 for converting a logic address from the memory instruction into an actual address. The NAND flash memory control unit 350 is coupled to the error correction code unit 340 and the block address translation table unit 345 for actually reading/writing data to/from the NAND flash memory 230. The main control logic unit 355 is coupled to the first buffer access unit 325, the second buffer access unit 335 and the block address translation table unit 345. The main control logic unit 355 controls the reading of data not yet registered inside the buffer region 310 from the NAND flash memory 230, determines if the requested data of a memory instruction is already in the buffer region 310 or not and controls the steps for writing stored data from the buffer region 310 to the NAND flash memory 230.

The list of memory instructions includes memory read, memory write and memory configure. Hence, operation of the control logic unit 320 may be explained under several conditions. On starting the system, the control logic unit 320 will download boot codes from the NAND flash memory 230 to the buffer region 310 so that an execution in place (XIP) function is provided. During downloading, the error correction code unit 340 will correct any reading errors to increase reliability.

On receiving a memory read instruction, the main control logic unit 355 will check if the requested data is already stored inside the buffer region 310. If the requested data is in the buffer region 310, the data is directly retrieved in response to the memory read instruction. If the requested data is absent, logic address of the memory read instruction is converted by the block address translation unit 345 into an actual address corresponding to the NAND flash memory. The data is read from the NAND flash memory through the NAND flash memory control unit 350. In the reading process, any errors are corrected by the error correction code unit 340 before transferring to the buffer region 310 via the second buffer access unit 335 and the buffer control logic unit 330. Thereafter, the requested data is provided through the first buffer access unit 325. During the waiting period, several modes of operation are possible. One way is to prevent other devices from using the bus until the requested data is returned. A second way is to release the bus to other devices and wait for the next retry so that the data may be read without any delays. A third way is to release the bus to other devices while the requested data is read from the NAND flash memory 230 and transferred to the buffer region 310. When the data is in the buffer region 310, an interrupt request is issued to take back the bus. Anyone familiar with system operation may select appropriate operating modes to improve system performance.

On receiving a memory write instruction, the write-in data is transferred to the buffer region 310 via the first buffer access unit 325 and the buffer control logic unit 330. Thereafter, the data is written into the NAND flash memory 230 in steps via the second buffer access unit 335 and the NAND flash memory control unit 350. On receiving a memory configure instruction, the main control logic unit 355 directly executes the memory configure instruction. The flash memory bridging device 300 supports 8/16/32 bit synchronous/asynchronous NOR flash memory interface, other memory configurations such as 4M×8, 16M×8, 32M×8, 64M×8 as well as interleave/non-interleave modes.

According to the aforementioned description of flash memory bridging device, a flash memory bridging method can be used to simulate the operation of a NOR flash memory. Ultimately, a NAND flash memory may communicate with a NOR flash memory interface via a flash memory bridging device. FIG. 4 is a flow chart showing the steps required to bridge flash memory according to the invention. As shown in FIG. 4, the method includes the following steps. In step S410, a memory instruction is received. The type of memory instruction is investigated in step S420. If the memory instruction is a memory read instruction or case=1, determine if the requested data is already stored inside the flash memory bridging device in step S430. If the requested data is in the flash memory bridging device, step S450 is executed to respond to the memory read instruction. On the other hand, if the requested data is not in the flash memory bridging device, step S440 is executed to read the data from the NAND flash memory before executing step S450 to respond to the memory read instruction. If the memory instruction is determined to be a memory write instruction or case=2 in step S420, the data is stored inside the flash memory bridging device in step S460. Thereafter, the data is gradually written from the flash memory bridging device to the NAND flash memory in step S470. If the memory instruction is determined to be a memory configure instruction or case=3, the memory configure instruction is executed in step S480. When data is read from the NAND flash memory, any errors in the data are first corrected to improve reliability. In fact, this invention can be regarded as using a flash memory bridging device to provide cache control logic. If the requested data resides in the storage region, the response is immediate. If the requested data is not in the storage region, errors are corrected during the reading operation although there is a slight delay.

In conclusion, using NAND flash memory to simulate the operation of the NOR flash memory and store program code and data not only lowers production cost, but also improves overall performance and reliability of the system.

It apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flash memory bridging device connected to a NOR flash memory interface for using a NAND flash memory to simulate the operation of a NOR flash memory, comprising:
a buffer region for storing data corresponding to a portion of the address of the NAND flash memory; and
a control logic unit coupled to the buffer region for receiving a memory instruction, executing the instruction and responding to the request of the memory instruction.

2. The flash memory bridging device of claim 1, wherein the control logic unit further comprising:
a first buffer access unit serving as an access interface between the NOR flash memory interface and the buffer region;
a buffer control logic unit coupled to the first buffer access unit and the buffer region for controlling reading/writing in the buffer region;
a second buffer access unit coupled to the buffer control logic unit serving as an access interface between the NAND flash memory and the buffer region;
an error correction code unit coupled to the second buffer access unit for correcting any error in the data read out from the NAND flash memory;
a block address translation table unit coupled to the second buffer access unit for converting a logic address of the memory instruction into an physical address;
a NAND flash memory control unit coupled to the error correction code unit and the block address translation table unit for reading/writing from/to the NAND flash memory; and
a main control logic unit coupled to the first buffer access unit, the second buffer access unit and the block address translation table unit for controlling the reading of non-recorded data from the NAND flash memory to the buffer region, determining if the data requested by the memory instruction is already in the buffer region and sequencing the writing of data from the buffer region to the NAND flash memory.

3. The flash memory bridging device of claim 1, wherein the memory instruction includes memory read instruction, memory write instruction and memory configure instruction.

4. The flash memory bridging device of claim 1, wherein the control logic unit supports 8/16/32 bit synchronous/non-synchronous interface.

5. The flash memory bridging device of claim 1, wherein the control logic unit supports different memory configurations including 4M×8, 16M×8, 32M×8, 64M×8 as well as interleave/non-interleave mode.

6. The flash memory bridging device of claim 1, wherein the control logic unit downloads boot codes from the NAND flash memory to the buffer region on system start-up.

7. The flash memory bridging device of claim 1, wherein the buffer region includes a plurality of buffering devices capable of operating in an interleave mode.

8. An application system for a flash memory bridging device, comprising:
a memory control chip, wherein the memory control chip supports a NOR flash memory interface for linking with a NOR flash memory;
a NAND flash memory for holding program codes for the system; and
a flash memory bridging device coupled to the memory control chip and the NAND flash memory for using the NAND flash memory to simulate the operation of the NOR flash memory.

9. The application system of claim 8, wherein the flash memory bridging device further comprises:
a buffer region for holding data corresponding to a portion of the NAND flash memory; and
a control logic unit coupled to the buffer region for receiving a memory instruction issued from the memory control chip, determining the nature of the memory instruction, executing the instruction and responding to the request of the instruction.

10. The application system of claim 9, wherein the control logic unit further includes:
a first buffer access unit serving as an access interface between the NOR flash memory interface and the buffer region;
a buffer control logic unit coupled to the first buffer access unit and the buffer region for controlling reading/writing in the buffer region;
a second buffer access unit coupled to the buffer control logic unit serving as an access interface between the NAND flash memory and the buffer region;
an error correction code unit coupled to the second buffer access unit for correcting any error in the data read out from the NAND flash memory;
a block address translation table unit coupled to the second buffer access unit for converting a logic address of the memory instruction into a physical address;
a NAND flash memory control unit coupled to the error correction code unit and the block address translation table unit for reading/writing from/to the NAND flash memory; and
a main control logic unit coupled to the first buffer access unit, the second buffer access unit and the block address translation table unit for controlling the reading of non-recorded data from the NAND flash memory to the buffer region, determining if the data requested by the memory instruction is already in the buffer region and sequencing the writing of data from the buffer region to the NAND flash memory.

11. The application system of claim 9, wherein the memory instruction includes memory read instruction, memory write instruction and memory configure instruction.

12. The application system of claim 8, wherein the control logic unit supports 8/16/32 bit synchronous/non-synchronous interface.

13. The application system of claim 8, wherein the control logic unit supports different memory configurations including 4M×8, 16M×8, 32M×8, 64M×8 as well as interleave/non-interleave mode.

14. The application system of claim 8, wherein the control logic unit downloads boot codes from the NAND flash memory to the buffer region on system start-up.

15. A bridging method for connecting a NAND flash memory to a NOR flash memory via a flash memory bridging device capable of simulating the operation of a NOR flash memory, comprising the steps of:
receiving a memory instruction;
if the memory instruction is a memory read instruction and the requested data is in the flash memory bridging device, respond to the memory read instruction;
if the memory instruction is a memory read instruction and the requested data is not within the flash memory bridging device, retrieve the requested data from the NAND flash memory before responding to the memory read instruction;
if the memory instruction is a write instruction, the data is stored inside the flash memory bridging device before writing to the NAND flash memory; and
if the memory instruction is a memory configure instruction, the memory configure instruction is executed.

16. The bridging method of claim 15, wherein any error in the data read from the NAND flash memory is corrected before sending to the flash memory bridging device.

17. A bridging method for connecting a NAND flash memory to a NOR flash via a flash memory bridging device capable of simulating the operation of a NOR flash memory, comprising the steps of:
receiving a memory instruction;
if the memory instruction is a memory read instruction and the requested data is in the flash memory bridging device, respond to the memory read instruction; and
if the memory instruction is a memory read instruction and the requested data is not within the flash memory bridging device, retrieve the requested data from the NAND flash memory before responding to the memory read instruction;

18. The bridging method of claim 17, wherein any error in the data read from the NAND flash memory is corrected before sending to the flash memory bridging device.

19. A bridging method for connecting a NAND flash memory to a NOR flash via a flash memory bridging device capable of simulating the operation of a NOR flash memory, comprising the steps of:
receiving a memory instruction;
if the memory instruction is a write instruction, the data is stored inside the flash memory bridging device before writing to the NAND flash memory; and
if the memory instruction is a memory configure instruction, the memory configure instruction is executed.
